(19) United States
(12) Patent Application Publication
(10) Pub. No.: US 2026/0189150 A1
(43) Pub. Date: Jul. 2, 2026

(54) DC/DC CONVERTER

(71) Applicant: HELLA GMBH & CO. KGAA, Lippstadt (DE)

(72) Inventors: Tobias Herrmann, Paderborn (DE); Jonas Issing, Lippstadt (DE); Mario Schröder, Soest (DE)

(21) Appl. No.: 19/548,416

(22) Filed: Feb. 24, 2026

Related U.S. Application Data
(63) Continuation of application No. PCT/EP2024/073277, filed on Aug. 20, 2024.

(30) Foreign Application Priority Data
Aug. 29, 2023 (DE) 102023123180.4

(51) Int. Cl. H02M 3/335; G01R 31/62

(52) U.S. Cl. CPC H02M 3/33573; G01R 31/62; H02M 3/33592

(57) ABSTRACT

The present invention relates to a DC-DC converter. The DC-DC converter includes a transformer; an input circuit configured to receive an input DC voltage (Ueg) and to provide an input AC voltage (Uew) to the transformer; and an output circuit configured to receive an output AC voltage (Uaw) from the transformer and to provide an output DC voltage (Uag), wherein a leakage inductance estimating device is provided which is configured to determine, to receive, or both to determine and to receive operating parameters (P-De, P-T, P-Ie1, P-Ie2, P-Ueg, P-Da, P-Uag) of the input circuit and the output circuit and, on the basis of the operating parameters (P-De, P-T, P-Ie1, P-Ie2, P-Ueg, P-Da, P-Uag), to determine a leakage inductance parameter (P-L) that estimates a leakage inductance of the transformer.

### CROSS-REFERENCE TO RELATED APPLICATIONS

The present application is a continuation of PCT/EP2024/073277, filed Aug. 20, 2024, which claims the benefit of German Patent Application 10-2023-123-180.4, filed Aug. 29, 2023, the disclosures of which are incorporated by reference in their entirety.

### FIELD OF THE INVENTION

The present invention relates to a DC/DC converter including: a transformer; an input circuit configured to receive an input DC voltage and to provide an input AC voltage to the transformer; and an output circuit configured to receive an output AC voltage from the transformer and to provide an output DC voltage.

### BACKGROUND OF THE INVENTION

Such DC/DC converters are known from the prior art, wherein the transformer creates a galvanic separation between the input circuit and the output circuit. Due to manufacturing constraints, transformers or transformer circuits generally exhibit a relatively large tolerance with regard to their leakage inductance, wherein the term “leakage inductance” encompasses all inductances electrically connected in series to an input winding of the transformer that generate a magnetic flux not flowing through an output winding of the transformer, such as line inductances or also inductances provided as discrete components connected in series with the input winding of the transformer. Since the power limit of the DC/DC converter is strongly influenced by the actual leakage inductance of the transformer, the actual leakage inductance of the transformer is typically determined by relatively complex measurements, and the DC/DC converter is calibrated based on the leakage inductance of the transformer determined by measurement.

### SUMMARY OF THE INVENTION

In light of this, the object at hand is to create a DC/DC converter that is relatively easy to calibrate. According to the invention, this object is achieved by a DC/DC converter with the features of the current embodiments.

The DC/DC converter according to an embodiment of the invention comprises a transformer, i.e., a component with at least one input winding and at least one output winding, which are magnetically coupled in such a way that when an input AC voltage is applied to the at least one input winding, an output AC voltage is induced in the at least one output winding. The ratio between the input AC voltage and the output AC voltage can be determined, in particular, by the number of turns of the at least one input winding and the at least one output winding.

The DC/DC converter according to an embodiment of the invention further comprises an input circuit which is configured to receive, i.e. to be provided with, an input DC voltage from a DC voltage source or an upstream circuit and to provide an input AC voltage to the transformer, in particular to at least one input winding of the transformer. The input circuit therefore comprises an inverter device that converts the input DC voltage into the input AC voltage, wherein the inverter device can in principle be designed in any manner known from the prior art.

The DC/DC converter according to an embodiment of the invention further comprises an output circuit which is configured to receive an output AC voltage from the transformer, in particular from the at least one output winding of the transformer, i.e., to be provided therewith by the transformer, and to provide an output DC voltage to a consumer or a downstream circuit. The output circuit therefore comprises a rectifier device that converts the output AC voltage into the output DC voltage, wherein the rectifier device can in principle be designed in any manner known from the prior art.

According to an embodiment of the invention, the DC/DC converter further comprises a leakage inductance estimating device that is configured to determine and/or to receive operating parameters of the input circuit and of the output circuit. The leakage inductance estimating device can, for example, be connected to the input circuit and/or to the output circuit via a suitable electrical connection in order to measure one or more electrical parameters of the input circuit and/or the output circuit, which can specify, for example, an electrical voltage or an electrical current of the input circuit or the output circuit, using one or more measuring devices. Alternatively or additionally, the leakage inductance estimating device can also be connected to the input circuit and/or to the output circuit via a data line, for example, in order to read out or be provided with an operating parameter from the input circuit or the output circuit in digital form, for example, from a control device or a monitoring device of the input circuit or the output circuit.

According to an embodiment of the invention, the leakage inductance estimating device is further configured to determine, based on the operating parameters of the input circuit and the output circuit, a leakage inductance parameter that estimates a leakage inductance of the transformer. This enables relatively simple calibration of the DC/DC converter according to the invention, since no special, relatively complex measurements need to be carried out to determine or estimate the leakage inductance of the transformer.

Preferably, the leakage inductance estimating device comprises a computing unit to which the operating parameters are provided and which is configured to calculate the leakage inductance parameter based on the operating parameters using a stored algorithm. This allows the leakage inductance parameter to be determined relatively easily. Preferably, the algorithm stored in the computing unit is substantially based on a single mathematical formula that comprises all the operating parameters provided. The computing unit can be implemented, for example, by a microcontroller or a suitably designed ASIC.

In a preferred embodiment, the input circuit and/or the output circuit comprise a plurality of semiconductor switches which are connected in a known manner in the form of a bridge circuit, wherein at least one control device is present which is configured to provide periodic control signals to the semiconductor switches of the input circuit and/or to the semiconductor switches of the output circuit in order to control the semiconductor switches. This allows for a simple conversion of the input DC voltage into the input AC voltage in the input circuit and/or a conversion of the output AC voltage into the output DC voltage in the output circuit. It is expressly pointed out that, within the meaning of the present invention, the term “control device” refers to both a device for controlling (open loop) and a device for regulating (closed loop), meaning that the “control device” can also be a regulating device in technical terms. Preferably, both the input circuit and the output circuit each comprise a plurality of semiconductor switches connected in the form of a bridge circuit, wherein the semiconductor switches of the input circuit and the semiconductor switches of the output circuit are typically provided with different periodic control signals, in particular having different duty cycles. Here, it is conceivable that the semiconductor switches of the input circuit and the semiconductor switches of the output circuit are controlled by a single control device, or that the input circuit and the output circuit each have their own control device for controlling the respective semiconductor switches.

Preferably, the operating parameters present in the leakage inductance estimating device comprise at least one duty cycle parameter, which specifies a duty cycle of a periodic control signal provided by the control device to the semiconductor switches of the input circuit or to the semiconductor switches of the output circuit. Preferably, the duty cycle parameter of the leakage inductance estimating device is provided by the control device. However, it is also conceivable that the leakage inductance estimating device is configured to determine the duty cycle by measurement. In the case that both the input circuit and the output circuit each comprise semiconductor switches, the operating parameters preferably comprise two duty cycle parameters, wherein one duty cycle parameter specifies the duty cycle of the periodic control signals provided to the semiconductor switches of the input circuit, and the other duty cycle parameter specifies the duty cycle of the periodic control signals provided to the semiconductor switches of the output circuit. This makes it possible to determine a relatively accurate leakage inductance parameter in a relatively simple manner.

Preferably, the operating parameters present in the leakage inductance estimating device comprise a period duration parameter that specifies a period duration of a periodic control signal provided by the control device to the semiconductor switches of the input circuit and/or to the semiconductor switches of the output circuit. Preferably, the period duration parameter of the leakage inductance estimating device is provided by the control device. However, it is also conceivable that the leakage inductance estimating device is configured to determine the period duration parameter by measurement. This makes it possible to determine a relatively accurate leakage inductance parameter in a relatively simple manner.

In a preferred embodiment, the input circuit and/or the output circuit comprise at least one inductance that is electrically connected to a bridge point of the bridge circuit of the input circuit or the output circuit located between two of the semiconductor switches, and the operating parameters comprise at least one current parameter that specifies an electric current flowing through the inductance. The current parameter can be provided to the leakage inductance estimating device by the input circuit or the output circuit, for example by a monitoring device of the input circuit or the output circuit, or the leakage inductance estimating device can be configured to determine the current parameter by measurement. In a particularly preferred embodiment, the input circuit or the output circuit comprises a number of inductances corresponding to the number of half-bridges in the bridge circuit, each of which is electrically connected to the bridge point of one of the half-bridges, and the operating parameters for each inductance comprise an individual current parameter, each of which specifies the electric current flowing through the respective inductance. This makes it possible to determine a relatively accurate leakage inductance parameter in a relatively simple manner.

Preferably, the control device is provided with the leakage inductance parameter, and the control device is configured to adjust a period duration of a periodic control signal provided to the semiconductor switches of the input circuit and/or to the semiconductor switches of the output circuit based on the leakage inductance parameter. If the input circuit and the output circuit each have their own control device, the leakage inductance parameter is preferably provided to both control devices, and both control devices are configured to adjust the period duration of the control signals provided by the respective control device based on the leakage inductance parameter. This makes it possible to compensate for the effects of the transformer's leakage inductance in an easy manner.

In a preferred embodiment, the operating parameters comprise at least one input circuit voltage parameter which specifies an electrical voltage of the input circuit and at least one output circuit voltage parameter which specifies an electrical voltage of the output circuit. The input circuit voltage parameter and the output circuit voltage parameter may be provided to the leakage inductance estimating device by the input circuit and the output circuit, for example by monitoring devices of the input circuit and the output circuit, or the leakage inductance estimating device may be configured to determine the input circuit voltage parameter and the output circuit voltage parameter by measurement. This makes it possible to determine a relatively accurate leakage inductance parameter in a relatively simple manner.

### BRIEF DESCRIPTION OF THE DRAWING

An exemplary embodiment of the present invention is described below with reference to the accompanying drawings:

FIG. 1 shows a schematic diagram of a DC/DC converter according to an embodiment of the invention.

### DETAILED DESCRIPTION OF THE CURRENT EMBODIMENT

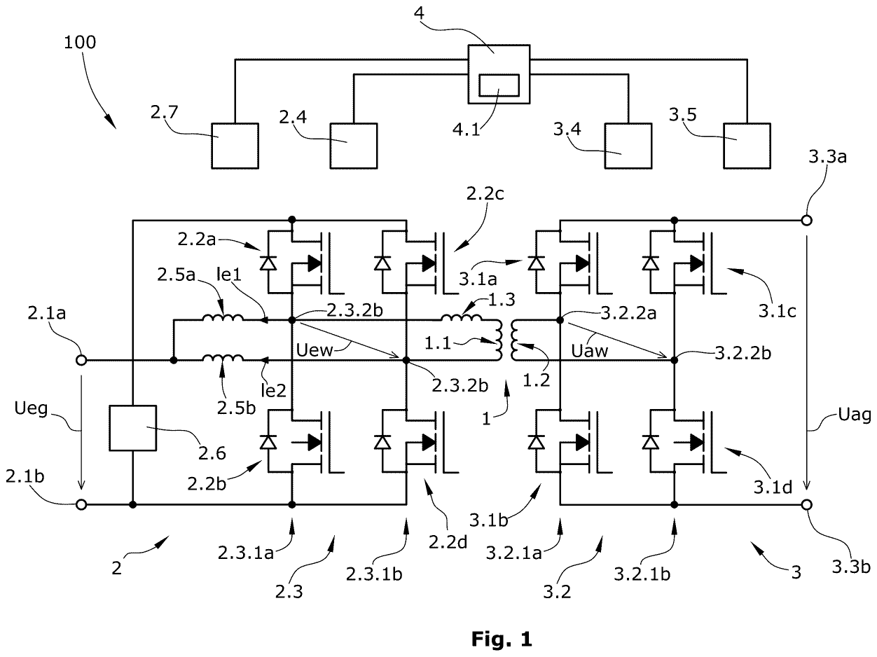

FIG. 1 shows a DC/DC converter 100 according to the invention, which comprises a transformer 1, an input circuit 2, an output circuit 3, and a leakage inductance estimating device 4.

Transformer 1 comprises an input winding 1.1 with a number of turns N1, an output winding 1.2 with a number of turns N2, and a transformer inductance 1.3, which in the schematic diagram shown is intended to illustrate a leakage inductance of transformer 1.

The input circuit 2 is configured to receive an input DC voltage Ueg at the input terminals 2.1a, 2.1b.

The input circuit 2 comprises four semiconductor switches 2.2a-2.2d which are connected in the form of a bridge circuit 2.3, wherein a first semiconductor switch 2.2a and a second semiconductor switch 2.2b are arranged in a first half-bridge 2.3.1a of the bridge circuit 2.3, and wherein a third semiconductor switch 2.2c and a fourth semiconductor switch 2.2d are arranged in a second half-bridge 2.3.1b of the bridge circuit 2.3.

The two half-bridges 2.3.1a, 2.3.1b of the bridge circuit 2.3 are each electrically connected to a terminal block 2.6, which comprises one or more capacitors (not shown here for reasons of clarity).

Via a first bridge point 2.3.2a located on the first half-bridge 2.3.1a between the first semiconductor switch 2.2a and the second semiconductor switch 2.2b, and via a second bridge point 2.3.2b located on the second half-bridge 2.3.1b between the third semiconductor switch 2.2c and the fourth semiconductor switch 2.2d, the bridge circuit 2.3 is electrically connected to the transformer inductance 1.3 and the input winding 1.1 of the transformer 1.

The input circuit 2 further comprises a control device 2.4 which is electrically connected to the control inputs of all four semiconductor switches 2.2a-2.2d (not shown here for reasons of clarity) and which is configured to provide periodic control signals with a duty cycle De and a period duration T to the control inputs of the four semiconductor switches 2.2a-2.2d in order to control the four semiconductor switches 2.2a-2.2d.

Here, the control device 2.4 is configured to control the four semiconductor switches 2.2a-2.2d in a known manner such that an input AC voltage Uew is applied between the bridge points 2.3.2a, 2.3.2b of the bridge circuit 2.3 during operation and is thus provided to the transformer 1.

The input circuit 2 further comprises a first input circuit inductance 2.5a and a second input circuit inductance 2.5b, wherein the first input circuit inductance 2.5a is electrically connected on one side to the first bridge point 2.3.2a and on the other side to the first input terminal 2.1a, and wherein the second input circuit inductance 2.5b is electrically connected on one side to the second bridge point 2.3.2b and on the other side to the first input terminal 2.1a.

The input circuit 2 further comprises a monitoring device 2.7 which is configured to determine a first input circuit current parameter P-Ie1 which specifies an electrical input circuit current Ie1 flowing through the first input circuit inductance 2.5a, a second input circuit current parameter P-Ie2 which specifies an electrical input circuit current Ie2 flowing through the second input circuit inductance 2.5b, and an input circuit voltage parameter P-Ueg which specifies the input DC voltage Ueg applied to the input terminals 2.1a, 2.1b by measurement.

The output circuit 3 comprises four semiconductor switches 3.1a-3.1d which are connected in the form of a bridge circuit 3.2, wherein a first semiconductor switch 3.1a and a second semiconductor switch 3.1b are arranged in a first half-bridge 3.2.1a of the bridge circuit 3.2, and wherein a third semiconductor switch 3.1c and a fourth semiconductor switch 3.1d are arranged in a second half-bridge 3.2.1b of the bridge circuit 3.2.

The two half-bridges 3.2.1a, 3.2.1b of the bridge circuit 3.2 are each electrically connected to the output terminals 3.3a, 3.3b of the output circuit 3.

Via a first bridge point 3.2.2a located on the first half-bridge 3.2.1a between the first semiconductor switch 3.1a and the second semiconductor switch 3.1b, and via a second bridge point 3.2.2b located on the second half-bridge 3.2.1b between the third semiconductor switch 3.1c and the fourth semiconductor switch 3.1d, the bridge circuit 3.2 is electrically connected to the output winding 1.2 of the transformer 1, so that during operation an output AC voltage Uaw is applied between the bridge points 3.2.2a, 3.2.2b of the output circuit 3, the amplitude of which depends on the ratio N1/N2 between the number of turns N1 of the input winding 1.1 of the transformer 1 and the number of turns N2 of the output winding 1.2 of the transformer 1.

During operation, the output circuit 3 therefore receives the output AC voltage Uaw from the transformer 1 via bridge points 3.2.2a and 3.2.2b.

The output circuit 3 further comprises a control device 3.4 which is electrically connected to the control inputs of all four semiconductor switches 3.1a-3.1d (not shown here for reasons of clarity) and which is configured to provide periodic control signals with a duty cycle Da and a period duration T to the control inputs of the four semiconductor switches 3.1a-3.1d in order to control the four semiconductor switches 3.1a-3.1d.

Here, the control device 3.4 is configured to control the four semiconductor switches 3.1a-3.1d in a known manner so that, during operation, an output DC voltage Uag is applied between the output terminals 3.3a, 3.3b of the output circuit 3, and thus provided by the output circuit 3 via the output terminals 3.3a, 3.3b.

The output circuit 3 further comprises a monitoring device 3.5 which is configured to determine an output circuit voltage parameter P-Uag which specifies the output DC voltage Uag applied between the output terminals 3.3a, 3.3b by measurement.

The leakage inductance estimating device 4 is connected to the control device 2.4 and the monitoring device 2.7 of the input circuit 2, as well as to the control device 3.4 and the monitoring device 3.5 of the output circuit 3.

The leakage inductance estimating device 4 is configured to receive, as an operating parameter of the input circuit 2 from the control device 2.4 of the input circuit 2, a duty cycle parameter P-De specifying the duty cycle De and a period duration parameter P-T specifying the period duration T, and to receive, from the monitoring device 2.7 of the input circuit 2, the first input circuit current parameter P-Ie1, the second input circuit current parameter P-Ie2, and the input circuit voltage parameter P-Ueg.

The leakage inductance estimating device 4 is further configured to receive, as an operating parameter of the output circuit 3 from the control device 3.4 of the output circuit 3, a duty cycle parameter P-Da specifying the duty cycle Da, and to receive, from the monitoring device 3.5 of the output circuit 3, the output circuit voltage parameter P-Uag.

The leakage inductance estimating device 4 comprises a computing unit 4.1 which is provided with the aforementioned operating parameters of the input circuit 2 and the output circuit 3, and which is configured to calculate, by means of an algorithm based on the operating parameters, a leakage inductance parameter P-L which estimates an inductance value of the transformer inductance 1.3 and thus the leakage inductance of the transformer 1.

Computing unit 4.1 is specifically configured to calculate the leakage inductance parameter P-L according to the following mathematical formula:

$$P - L = \frac{{( P - Uag )}^{2} \cdot P - T}{{( \frac{N 1}{N 2} )}^{2} , P - Ueg \cdot ( P - le 1 + P - le 2 )} \cdot ( 1 - P - De ) \cdot ( \frac{P - Da}{2} - ( 1 - P - De ) )$$

The leakage inductance estimating device 4 is further configured to provide the determined leakage inductance parameter P-L to the control device 2.4 of the input circuit 2 and to the control device 3.4 of the output circuit 3, wherein the control device 2.4 of the input circuit 2 and the control device 3.4 of the output circuit 3 are configured to adjust the period duration T of the control signals provided to the four semiconductor switches 2.2a-2.2d of the input circuit 2 and to the four semiconductor switches 3.1a-3.1d of the output circuit 3 based on the received leakage inductance parameter P-L in order to compensate as well as possible for the effects of the leakage inductance of the transformer 1.

### LIST OF REFERENCE SIGNS

100 DC/DC converter
1 transformer
1.1 input winding
1.2 output winding
1.3 transformer inductance
2 input circuit
2.1a, 2.1b input terminals
2.2a-2.2d semiconductor switches
2.3 bridge circuit
2.3.1a, 2.3.1b half-bridges
2.3.2a, 2.3.2b bridge points
2.4 control device
2.5a, 2.5b input circuit inductances
2.6 terminal block
2.7 monitoring device
3 output circuit
3.1a-3.1d semiconductor switches
3.2 bridge circuit
3.2.1a, 3.2.1b half-bridges
3.2.2a, 3.2.2b bridge points
3.3a, 3.3b output terminals
3.4 control device
3.5 monitoring device
4 leakage inductance estimating device
4.1 computing unit
Ie1, Ie2 input circuit currents
Uag output DC voltage
Uaw output AC voltage
Ueg input DC voltage
Uew input AC voltage

The above description is that of a current embodiment of the invention. Various alterations and changes can be made without departing from the spirit and broader aspects of the invention. This disclosure is presented for illustrative purposes and should not be interpreted as an exhaustive description of all embodiments of the invention or to limit the scope of the claims to the specific elements illustrated or described in connection with these embodiments. Any reference to elements in the singular, for example, using the articles “a,” “an,” “the,” or “said,” is not to be construed as limiting the element to the singular.

1. A DC/DC converter comprising:
a transformer;
an input circuit configured to receive an input DC voltage (Ueg) and to provide an input AC voltage (Uew) to the transformer;
an output circuit configured to receive an output AC voltage (Uaw) from the transformer and to provide an output DC voltage (Uag); and
a leakage inductance estimating device configured to determine, to receive, or both to determine and to receive operating parameters (P-De, P-T, P-Ie1, P-Ie2, P-Ueg, P-Da, P-Uag) of the input circuit and the output circuit, and on the basis of the operating parameters (P-De, P-T, P-Ie1, P-Ie2, P-Ueg, P-Da, P-Uag), to determine a leakage inductance parameter (P-L) that estimates a leakage inductance of the transformer.

2. The DC/DC converter according to claim 1, wherein the leakage inductance estimating device comprises a computing unit to which the operating parameters (P-De, P-T, P-Ie1, P-Ie2, P-Ueg, P-Da, P-Uag) are provided, the computing unit being configured to calculate the leakage inductance parameter (P-L) based on the operating parameters (P-De, P-T, P-Ie1, P-Ie2, P-Ueg, P-Da, P-Uag).

3. The DC/DC converter according to claim 1, wherein at least one of the input circuit and the output circuit comprises a plurality of semiconductor switches connected in the form of a bridge circuit, and wherein a control device is present which is configured to provide periodic control signals to the semiconductor switches of at least one of the input circuit and the output circuit.

4. The DC/DC converter according to claim 3, wherein the operating parameters (P-De, P-T, P-Ie1, P-Ie2, P-Ueg, P-Da, P-Uag) comprise a duty cycle parameter (P-De, P-Da) which specifies a duty cycle (De, Da) of a periodic control signal provided by the control device to the semiconductor switches of the input circuit or to the semiconductor switches of the output circuit.

5. The DC/DC converter according to claim 3, wherein the operating parameters (P-De, P-T, P-Ie1, P-Ie2, P-Ueg, P-Da, P-Uag) comprise a period duration parameter (P-T) which specifies a period duration (T) of a periodic control signal provided by the control device to the semiconductor switches of at least one of the input circuit and the output circuit.

6. The DC/DC converter according to claim 3, wherein at least one of the input circuit and the output circuit comprises an inductance electrically connected to a bridge point located between two of the semiconductor switches, and wherein the operating parameters (P-De, P-T, P-Ie1, P-Ie2, P-Ueg, P-Da, P-Uag) comprise a current parameter (P-Ie1, P-Ie2) which specifies an electric current (Ie1, Ie2) flowing through the inductance.

7. The DC/DC converter according to claim 3, wherein the leakage inductance parameter (P-L) is provided to the control device, and wherein the control device is configured to adjust a period duration (T) of a periodic control signal provided to the semiconductor switches of at least one of the input circuit and the output circuit based on the leakage inductance parameter (P-L).

8. The DC/DC converter according to claim 1, wherein the operating parameters (P-De, P-T, P-Ie1, P-Ie2, P-Ueg, P-Da, P-Uag) comprise an input circuit voltage parameter (P-Ueg) specifying an electrical voltage (Ueg) of the input circuit and an output circuit voltage parameter (P-Uag) specifying an electrical voltage (Uag) of the output circuit.
